(19) United States
(12) Patent Application Publication
(10) Pub. No.: US 2025/0040053 A1
(43) Pub. Date: Jan. 30, 2025

(54) SEMICONDUCTOR DEVICE

(71) Applicants: KABUSHIKI KAISHA TOSHIBA, Tokyo (JP); Toshiba Electronic Devices & Storage Corporation, Tokyo (JP)

(72) Inventor: Eitaro Miyake, Tachikawa Tokyo (JP)

(21) Appl. No.: 18/602,927

(22) Filed: Mar. 12, 2024

(30) Foreign Application Priority Data
Jul. 24, 2023 (JP) 2023-120009

(51) Int. Cl. H05K 1/18; H01L 23/00; H01L 23/498; H01L 25/065; H05K 1/14

(52) U.S. Cl. CPC H05K 1/181; H01L 23/49838; H01L 25/0655; H05K 1/144; H01L 24/32; H01L 24/48; H01L 24/73; H01L 2224/32225; H01L 2224/48225; H01L 2224/73265; H01L 2924/181

(57) ABSTRACT

According to one embodiment, a semiconductor device includes a first insulated circuit board, a second insulated circuit board, a first semiconductor chip and a first spacer. The first insulated circuit board includes a first conductive plate. The first conductive plate has a first conductive pattern. The first spacer is placed on the first conductive pattern. The first conductive pattern has a first side, a second side, a third side and a fourth side which surround the first spacer. The first side extends in a first direction. The second side continues to the first side and extends in a second direction that is orthogonal to the first direction. The third side continues to the second side and extends in the first direction. The fourth side continues to the third side and extends obliquely to the first direction and the second direction.

### CROSS-REFERENCE TO RELATED APPLICATIONS

This application is based upon and claims the benefit of priority from prior Japanese Patent Application No. 2023-120009, filed Jul. 24, 2023, the entire contents of which are incorporated herein by reference.

### FIELD

Embodiments described herein relate generally to a semiconductor device.

### BACKGROUND

A semiconductor device including an insulated circuit board on which semiconductor chips are mounted is known.

### BRIEF DESCRIPTION OF THE DRAWINGS

FIG. 1 is a perspective view showing an external shape of a semiconductor device according to a first embodiment.

FIG. 2 is a plan view showing a configuration of the semiconductor device according to the first embodiment.

FIG. 3 is a sectional view taken along line III-III in FIG. 2.

FIG. 4 is an enlarged view of a periphery of an inter-substrate spacer in the semiconductor device according to the first embodiment.

FIG. 5 is an enlarged view of a periphery of an inter-substrate spacer in a semiconductor device of a comparative example.

FIG. 6 is a plan view showing a configuration of a semiconductor device according to a second embodiment.

FIG. 7 is an enlarged view of a periphery of an inter-substrate spacer in the semiconductor device according to the second embodiment.

FIG. 8 is a plan view showing a configuration of a semiconductor device according to a third embodiment.

FIG. 9 is an enlarged view of a periphery of an inter-substrate spacer in the semiconductor device according to the third embodiment.

### DETAILED DESCRIPTION

In general, according to one embodiment, a semiconductor device includes a first insulated circuit board including a first conductive plate, a second conductive plate, and a first insulating substrate provided between the first conductive plate and the second conductive plate; a second insulated circuit board including a third conductive plate, a fourth conductive plate, and a second insulating substrate provided between the third conductive plate and the fourth conductive plate; a first semiconductor chip provided between the first insulated circuit board and the second insulated circuit board; and a first spacer provided between the first insulated circuit board and the second insulated circuit board. The first conductive plate has a first conductive pattern. The first spacer is placed on the first conductive pattern. The first conductive pattern has a first side, a second side, a third side and a fourth side which surround the first spacer. The first side extends in a first direction. The second side continues to the first side and extends in a second direction that is orthogonal to the first direction. The third side continues to the second side and extends in the first direction. The fourth side continues to the third side and extends obliquely to the first direction and the second direction.

Embodiments will be described below with reference to the drawings. In the following descriptions, the structural elements having the same function and same configuration are denoted by a common reference sign. Each of the embodiments exemplifies a device and a method for embodying the technical concept of the embodiment, and the technical concept does not limit the material, shape, structure, placement, etc. of the structural elements to the following matters.

### 1. First Embodiment

A semiconductor device according to a first embodiment will be described below. The semiconductor device includes a semiconductor chip and two insulated circuit boards between which the semiconductor chip is sandwiched from above and below, and has a package structure in which the semiconductor chip and insulated circuit boards are held by a mold material.

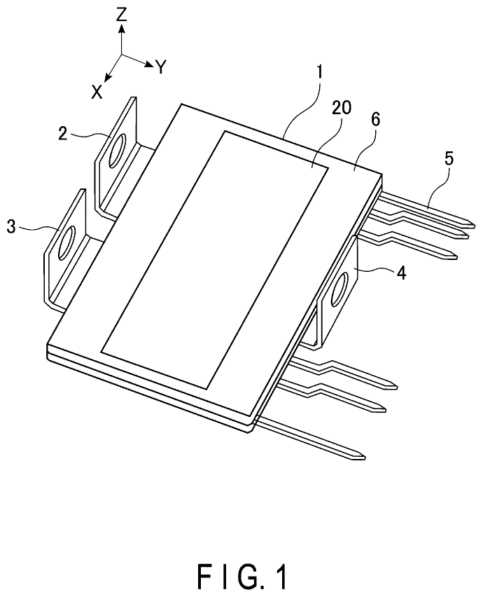

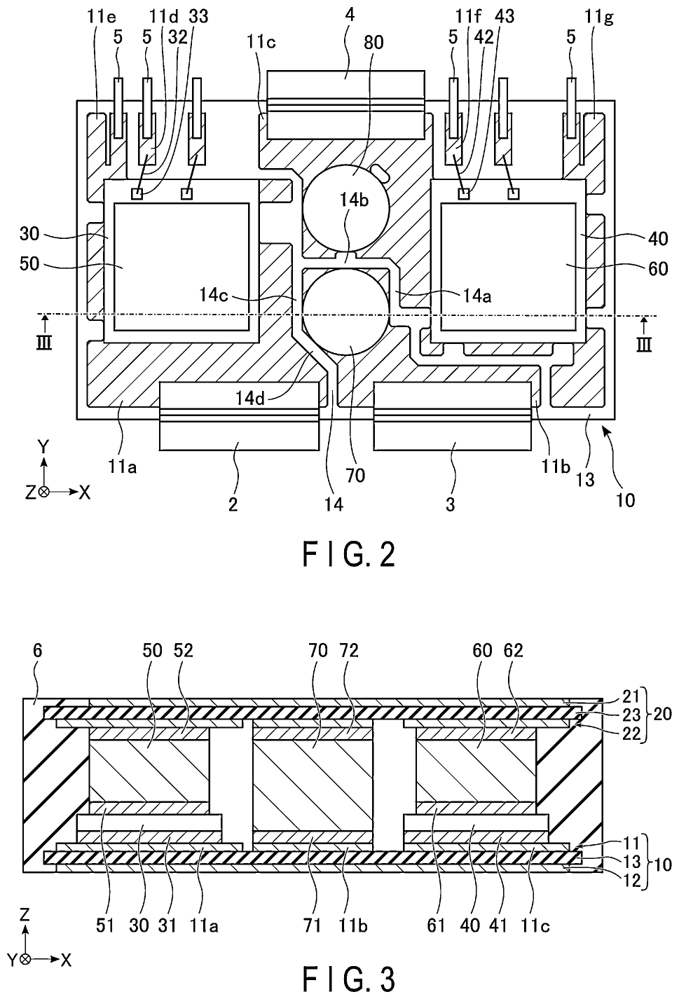

The configuration of the semiconductor device of the first embodiment will be described with reference to FIGS. 1, 2 and 3. FIG. 1 is a perspective view showing an external shape of the semiconductor device of the first embodiment. FIG. 2 is a plan view showing the configuration of the semiconductor device of the first embodiment. FIG. 3 is a sectional view taken along line III-III in FIG. 2.

The semiconductor device includes a main body 1, plate terminals 2, 3 and 4 and a plurality of lead terminals 5. The main body 1 includes a mold material 6, a lower insulated circuit board 10, an upper insulated circuit board 20, semiconductor chips 30 and 40, chip spacers 50 and 60 and inter-substrate spacers 70 and 80.

Each of the plate terminals 2, 3 and 4 is electrically coupled to a conductive pattern (or a circuit pattern) of the insulated circuit board 10. The lead terminals 5 are each electrically coupled to the semiconductor chips 30 and 40 or a conductive pattern. The plan view of FIG. 2 shows a configuration on the insulated circuit board 10 when viewed through the insulated circuit board 20 and the mold material 6.

As shown in FIG. 2, the semiconductor chip 30 is provided at one end of the insulated circuit board 10 in the X direction, and the semiconductor chip 40 is provided at the other end thereof in the X direction. The inter-substrate spacers 70 and 80 are provided in the Y direction between the semiconductor chips 30 and 40. Hereinafter, one side of the insulated circuit board 10 on which the semiconductor chip 30 is provided will be referred to as one end in the X direction, and the side thereof on which the semiconductor chip 40 is provided will be referred to as the other end in the X direction.

As shown in FIG. 3, the insulated circuit board 10 includes a conductive plate 11, a conductive plate 12 and a ceramic substrate 13. The ceramic substrate 13 is provided between the conductive plates 11 and 12. That is, the conductive plate 11 is placed on the top surface of the ceramic substrate 13, and the conductive plate 12 is placed on the bottom surface of the ceramic substrate 13. The thickness of each of the conductive plates 11 and 12 is, for example, about 0.4 mm. The conductive plates 11 and 12 contain copper, for example. The ceramic substrate 13 is formed of an insulating material and has electrical insulating properties.

The conductive plate 11 is partly removed in a certain pattern to form a slit 14. That is, the slit 14 is a groove provided in the conductive plate 11 and removed a part of the conductive plate 11.

The conductive plate 11 is separated into three conductive patterns (or circuit patterns) 11a, 11b and 11c by the slit 14. The conductive patterns 11a, 11b and 11c are electrically insulated from one another.

Similarly, the insulated circuit board 20 includes a conductive plate 21, a conductive plate 22 and a ceramic substrate 23. The ceramic substrate 23 is provided between the conductive plates 21 and 22. That is, the conductive plate 21 is placed on the top surface of the ceramic substrate 23, and the conductive plate 22 is placed on the bottom surface of the ceramic substrate 23. The thickness of each of the conductive plates 21 and 22 is, for example, about 0.4 mm. The conductive plates 21 and 22 contain copper, for example. The ceramic substrate 23 is formed of an insulating material and has electrical insulating properties.

Although not shown, the conductive plate 22 is separated into a plurality of conductive patterns (or circuit patterns) electrically insulated from one another by a slit.

The semiconductor chip 30 is provided on the conductive pattern 11a with a solder material 31 therebetween. The chip spacer 50 is provided on the semiconductor chip 30 with a solder material 51 therebetween. In addition, the conductive pattern of the conductive plate 22 is provided on the chip spacer 50 with a solder material 52 therebetween.

The semiconductor chip 30 includes, for example, a MOS field effect transistor (that is, MOSFET) or an insulated gate bipolar transistor (IGBT). It is assumed here that the semiconductor chip 30 is a MOS field effect transistor. The semiconductor chip 30 includes a gate, a source and a drain as electrodes.

For example, the drain of the semiconductor chip 30 is electrically coupled to the conductive pattern 11a through the solder material 31. The source of the semiconductor chip 30 is electrically coupled to the chip spacer 50 through the solder material 51.

The chip spacer 50 includes a conductive material and has conductivity. Thus, the source of the semiconductor chip 30 is electrically coupled to the conductive pattern of the conductive plate 22 through the solder material 51, chip spacer 50 and solder material 52. In addition, the chip spacer 50 functions as a heat dissipation path that dissipates heat from the semiconductor chip 30 to the insulated circuit board 20.

The inter-substrate spacer 70 is provided on the conductive pattern 11b with a solder material 71 therebetween. The conductive pattern of the conductive plate 22 is provided on the inter-substrate spacer 70 with a solder material 72 therebetween.

The inter-substrate spacer 70 has, for example, a circular shape when viewed from the Z direction and has a cylindrical shape having a thickness in the Z direction. The inter-substrate spacer 70 includes a conductive material and has conductivity. Thus, the conductive pattern 11b is electrically coupled to the conductive pattern of the conductive plate 22 through the solder material 71, inter-substrate spacer 70 and solder material 72.

The semiconductor chip 40 is provided on the conductive pattern 11c with a solder material 41 therebetween. The chip spacer 60 is provided on the semiconductor chip 40 with a solder material 61 therebetween. In addition, the conductive pattern of the conductive plate 22 is provided on the chip spacer 60 with a solder material 62 therebetween.

The semiconductor chip 40 includes, for example, a MOS field effect transistor or an IGBT. It is assumed here that the semiconductor chip 40 is a MOS field effect transistor. The semiconductor chip 40 includes a gate, a source and a drain as electrodes.

For example, the drain of the semiconductor chip 40 is electrically coupled to the conductive pattern 11c through the solder material 41. The source of the semiconductor chip 40 is electrically coupled to the chip spacer 60 through the solder material 61.

The chip spacer 60 includes a conductive material and has conductivity. Thus, the source of the semiconductor chip 40 is electrically coupled to the conductive pattern of the conductive plate 22 through the solder material 61, chip spacer 60 and solder material 62. In addition, the chip spacer 60 functions as a heat dissipation path that dissipates heat generated from the semiconductor chip 40 to the insulated circuit board 20.

The inter-substrate spacer 80 is provided on the conductive pattern 11c with a solder material therebetween. The conductive pattern of the conductive plate 22 are formed on the inter-substrate spacer 80 with a solder material therebetween.

The inter-substrate spacer 80 has, for example, a circular shape when viewed from the Z direction and has a cylindrical shape having a thickness in the Z direction. The inter-substrate spacer 80 includes a conductive material and has conductivity. Thus, the conductive pattern 11c is electrically coupled to the conductive pattern of the conductive plate 22 through the solder material, inter-substrate spacer 80 and solder material.

As shown in FIG. 2, the plate terminals 2 and 3 are provided at one end of the insulated circuit board 10 in the Y direction, and the plate terminal 4 is provided at the other end thereof in the Y direction. Hereinafter, one side of the insulated circuit board 10 on which the plate terminals 2 and 3 are provided will be referred to as one end in the Y direction, and the side thereof on which the plate terminal 4 is provided will be referred to as the other end in the Y direction.

The plate terminal 2 is placed on one end of the conductive pattern 11a in the Y direction. The plate terminal 2 is bonded to the conductive pattern 11a with a solder material therebetween. The plate terminal 2 is electrically coupled to the conductive pattern 11a. The plate terminal 3 is placed on one end of the conductive pattern 11b in the Y direction. The plate terminal 3 is bonded to the conductive pattern 11b with a solder material therebetween. The plate terminal 3 is electrically coupled to the conductive pattern 11b. In addition, the plate terminal 4 is placed on the other end of the conductive pattern 11c in the Y direction. The plate terminal 4 is bonded to the conductive pattern 11c with a solder material therebetween. The plate terminal 4 is electrically coupled to the conductive pattern 11c.

For example, a high voltage is applied to the plate terminal 2. The plate terminal 2 is also referred to as a P terminal, for example. A voltage that is lower than the high voltage applied to the plate terminal 2 is applied to the plate terminal 3. The plate terminal 3 is also referred to as an N terminal, for example. Then, the plate terminal 4 outputs either the high voltage from the plate terminal 2 or the low voltage from the plate terminal 3. The plate terminal 4 is also referred to as an AC terminal, for example. The thickness of each of the plate terminals 2, 3 and 4 is, for example, 0.8 mm.

In addition, the lead terminals 5 are provided at the other end of the insulated circuit board 10 in the Y direction.

Conductive patterns 11d and 11e are placed at the other end of the insulated circuit board 10 in the Y direction relative to the semiconductor chip 30. Each of the conductive patterns 11d and 11e is shaped like an island.

For example, one lead terminal 5 is bonded to the conductive pattern 11d with a solder material therebetween. The conductive pattern 11d is coupled to a pad 33 of the semiconductor chip 30 by a bonding wire 32. The pad 33 is coupled to the gate of the semiconductor chip 30. The lead terminal 5 is electrically coupled to the gate of the semiconductor chip 30 through the conductive pattern 11d, bonding wire 32 and pad 33.

Another lead terminal 5 is bonded to the conductive pattern 11e with a solder material therebetween. The lead terminal 5 is electrically coupled to the conductive pattern lie.

Conductive patterns 11f and 11g are placed at the other end of the insulated circuit board 10 in the Y direction relative to the semiconductor chip 40. Each of the conductive patterns 11f and 11g is shaped like an island.

For example, one lead terminal 5 is bonded to the conductive pattern 11f with a solder material therebetween. The conductive pattern 11f is coupled to a pad 43 of the semiconductor chip 40 by a bonding wire 42. The pad 43 is coupled to the gate of the semiconductor chip 40. The lead terminal 5 is electrically coupled to the gate of the semiconductor chip 40 through the conductive pattern 11f, bonding wire 42 and pad 43.

Another lead terminal 5 is bonded to the conductive pattern 11g with a solder material therebetween. The lead terminal 5 is electrically coupled to the conductive pattern 11g.

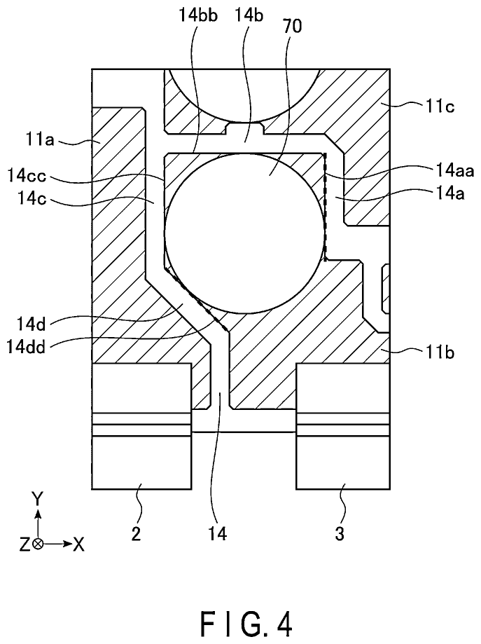

The conductive pattern lib in which the inter-substrate spacer 70 is bonded by the solder material 71 will be described with reference to FIG. 4. FIG. 4 is an enlarged view of the periphery of the inter-substrate spacer 70 in the semiconductor device of the first embodiment.

In FIG. 4, a first side 14aa of the conductive pattern lib is located on the right side (or at the other end) of the inter-substrate spacer 70 in the X direction when viewed from the Z direction in FIG. 4, that is, when viewed from above the surface of the conductive plate 11 of the insulated circuit board 10 (or when viewed from an orthogonal direction). A second side 14bb of the conductive pattern 11b is located on the upper side (or at the other end) of the inter-substrate spacer 70 in the Y direction. A third side 14cc of the conductive pattern 11b is located on the left side (or at one end) of the inter-substrate spacer 70 in the X direction. In addition, a fourth side 14dd of the conductive pattern 11b is located on the lower side (or at one end) of the inter-substrate spacer 70 in the Y direction.

The first, second, third and fourth sides 14aa, 14bb, 14cc and 14dd are consecutive ones and surround the inter-substrate spacer 70. The first side 14aa extends linearly in the Y direction. The second side 14bb extends linearly in the X direction. The third side 14cc extends linearly in the Y direction. The fourth side 14dd extends linearly so as to be oblique to the X and Y directions, in other words, to intersect with the X and Y directions.

The first and fourth sides 14aa and 14dd are located such that an interval between them decreases toward the lower side in the Y direction (or toward the one end). In other words, the first and fourth sides 14aa and 14dd are located such that an interval between them decreases toward a direction away from the inter-substrate spacer 70. In this case, the interval between the first and fourth sides 14aa and 14dd is smaller than the diameter of the inter-substrate spacer 70.

The slit 14 provided around the inter-substrate spacer 70 will be described below with reference to FIG. 4.

The inter-substrate spacer 70 has the shape of a circle. The slit 14 is provided around the inter-substrate spacer 70. The slit 14 includes a first portion 14a, a second portion 14b, a third portion 14c and a fourth portion 14d.

The first portion 14a is provided between the conductive patterns 11b and 11c. The first portion 14a is located in contact with the circumference of the inter-substrate spacer 70 when viewed from the Z direction, and extends linearly in the Y direction. Here, the circumference of the inter-substrate spacer 70 refers to a curve that forms the inter-substrate spacer 70 when viewed from the Z direction.

The second portion 14b continues to the first portion 14a between the conductive patterns 11b and 11c. The second portion 14b is located in contact with the circumference of the inter-substrate spacer 70 when viewed from the Z direction, and extends linearly in the X direction.

The third portion 14c continues to the second portion 14b between the conductive patterns 11b and 11a. The third portion 14c is located in contact with the circumference of the inter-substrate spacer 70 when viewed from the Z direction, and extends linearly in the Y direction.

The fourth portion 14d continues to the third portion 14c between the conductive patterns 11b and 11a. The fourth portion 14d is located in contact with the circumference of the inter-substrate spacer 70 when viewed from the Z direction. The fourth portion 14d extends linearly so as to be oblique to the X and Y directions, in other words, to intersect with the X and Y directions.

The second portion 14b continues to the first portion 14a without interruption. The third portion 14c continues to the second portion 14b without interruption. In addition, the fourth portion 14d continues to the third portion 14c without interruption. That is, the first, second, third and fourth portions 14a, 14b, 14c and 14d are surround the inter-substrate spacer 70.

The inter-substrate spacer 70 is bonded via a solder material to a region of the conductive pattern 11b that is surrounded by the first to fourth portions 14a, 14b, 14c and 14d.

With the first embodiment, a semiconductor device capable of decreasing the resistance and inductance of conductive patterns (circuit patterns) on an insulated circuit board can be provided.

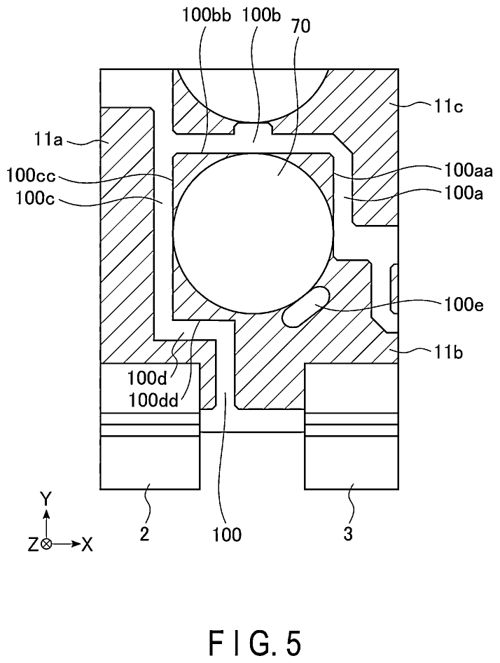

FIG. 5 is an enlarged view of the periphery of an inter-substrate spacer 70 in a semiconductor device of a comparative example. In the comparative example, a slit 100 corresponds to the slit 14.

As shown in FIG. 5, the slit 100 includes a first portion 100a, a second portion 100b, a third portion 100c and a fourth portion 100d, which surround the inter-substrate spacer 70. In other words, a conductive pattern lib includes a first side 100aa, a second side 100bb, a third side 100cc and a fourth side 100dd, which surround the inter-substrate spacer 70. A fifth portion 100e is located between the first and fourth portions 100a and 100d. This location prevents the inter-substrate spacer 70 from being displaced when the inter-substrate spacer 70 is soldered.

If the fourth portion 100d is provided to extend in the X direction and the fifth portion 100e is provided between the first and fourth portions 100a and 100d, the conductive pattern lib between the first and fourth portions 100a and 100d is narrowed on the lower right side of the inter-substrate spacer 70. Therefore, the resistance and inductance of the conductive pattern lib may increase. In addition, if the fourth portion 100d is provided to extend in the X direction in the third portion 100c extending in the Y direction, the edge portions of the conductive pattern lib, that is, the third and fourth sides 100cc and 100dd are orthogonal to each other. Therefore, the high-frequency components of an AC signal pass through the edge portions, which may cause the inductance to rise.

On the other hand, in the first embodiment, the fourth side 14dd of the conductive pattern 11b is located obliquely to the X and Y directions so as to be in contact with the inter-substrate spacer 70, that is, it is located in a downward to the right direction when viewed from the Z direction. In other words, the first and fourth sides 14aa and 14dd of the conductive pattern 11b are located so that an interval between them decreases toward a direction away from the inter-substrate spacer 70.

Focusing on the slit 14, the fourth portion 14d of the slit 14 is located obliquely to the X and Y directions so as to be in contact with the inter-substrate spacer 70, that is, it is located in a downward to the right direction when viewed from the Z direction. In other words, an interval between the first and fourth portions 14a and 14d of the slit 14 decreases toward a direction away from the inter-substrate spacer 70.

Thus, the fifth portion 100e need not be provided between the first and fourth portions 14a and 14d of the slit 14, with the result that the inter-substrate spacers 70 can be prevented from being displaced and the resistance and inductance of the conductive pattern 11b can be lowered. In addition, the third and fourth sides 14cc and 14dd of the conductive pattern 11b are located at an angle that is larger than a right angle. Therefore, the inductance caused by the high-frequency components of AC signals flowing through the conductive pattern 11b can be reduced more than that in the case where the third and fourth sides 14cc and 14dd are located at a right angle.

In the configuration of the first embodiment, the insulated circuit boards 10 and 20 can radiate heat generated from the semiconductor chips 30 and 40 and the conductive pattern to the outside from. Specifically, heat generated from the semiconductor chips 30 and 40 and the conductive pattern during operation of the semiconductor device is dissipated to the outside from both sides of the semiconductor device, that is, from the insulated circuit boards 10 and 20 placed above and below the semiconductor chips 30 and 40.

As described above, according to the semiconductor device of the first embodiment, the resistance and inductance of the conductive patterns (or the circuit patterns) on the insulated circuit boards can be lowered.

### 2. Second Embodiment

Next is a description of a semiconductor device of a second embodiment. The second embodiment is directed to an example in which the shape of the plate terminal 3 (N terminal) is improved in addition to the configuration of the first embodiment. The second embodiment will be mainly described regarding differences from the first embodiment.

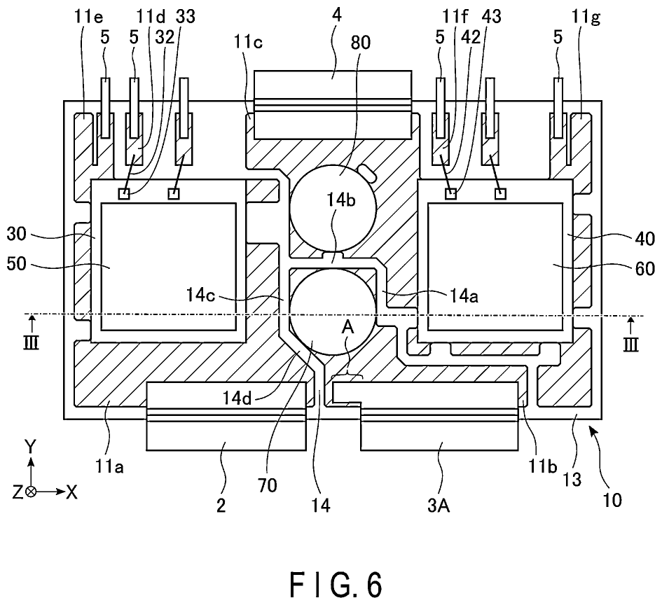

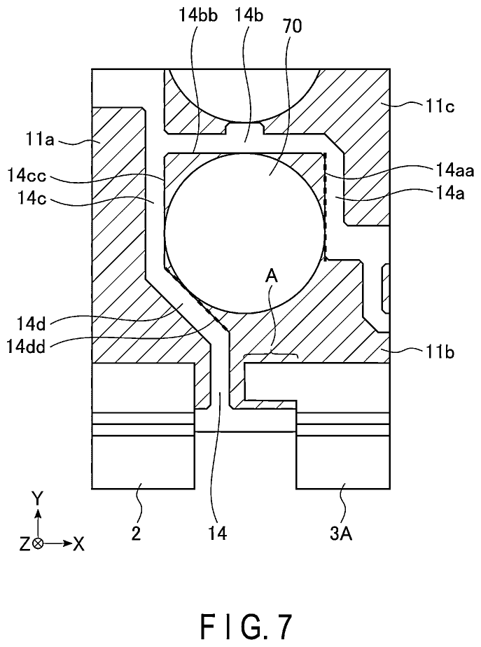

The configuration of the semiconductor device of the second embodiment will be described with reference to FIGS. 6 and 7.

In the semiconductor device of the second embodiment, the shape of a plate terminal 3A differs from that of the plate terminal 3 of the first embodiment. The other configurations are the same as those of the first embodiment.

FIG. 6 is a plan view showing a configuration of the semiconductor device of the second embodiment. FIG. 7 is an enlarged view of the periphery of an inter-substrate spacer 70 in the semiconductor device of the second embodiment.

The plate terminal 3A is located at one end of the conductive pattern 11b in the Y direction. The plate terminal 3A has a protruding portion A at one end in the X direction. That is, the plate terminal 3A has a rectangular shape and includes a protruding portion A protruding from one end of the rectangular shape in the X direction. In other words, the plate terminal 3A includes a rectangular portion having a rectangular shape and a protruding portion A that protrudes from one end of the rectangular portion in the X direction. The distance from one end of the rectangular portion in the X direction or the protruding portion A to the inter-substrate spacer 70 is shorter than the distance from the other end of the rectangular portion in the X direction to the inter-substrate spacer 70.

The protruding portion A overlaps the conductive pattern 11b in the Z direction. The plate terminal 3A including the protruding portion A is bonded to the conductive pattern 11b with a solder material therebetween and is electrically connected to the conductive pattern 11b. The thickness of the plate terminal 3A is, for example, 0.8 mm.

In the second embodiment, the plate terminal 3A the area of which is larger than that of the plate terminal 3 is electrically connected to the conductive pattern 11b. That is, in the second embodiment, in addition to the plate terminal 3 of the first embodiment, the protruding portion A is also electrically connected to the conductive pattern 11b.

The conductive pattern 11b close to one end of the plate terminal 3A in the X direction is a current path through which current intensively flows between the plate terminal 3A and the inter-substrate spacer 70. Since the protruding portion A is provided on the current path, only the conductive pattern 11b can be used to shorten the current flow path.

Thus, the resistance and inductance can be further lowered at the plate terminal 3A and conductive pattern 11b.

As described above, according to the semiconductor device of the second embodiment, providing the plate terminal 3A having an increased area in addition to the structure of the first embodiment makes it possible to lower the resistance and inductance of the conductive patterns (or circuit patterns) on the insulated circuit board more than in the first embodiment.

### 3. Third Embodiment

Next is a description of a semiconductor device of a third embodiment. The third embodiment is directed to a case in which the shape of the plate terminal 3A (N terminal) is improved more than that in the second embodiment. The third embodiment will be mainly described regarding differences from the first embodiment.

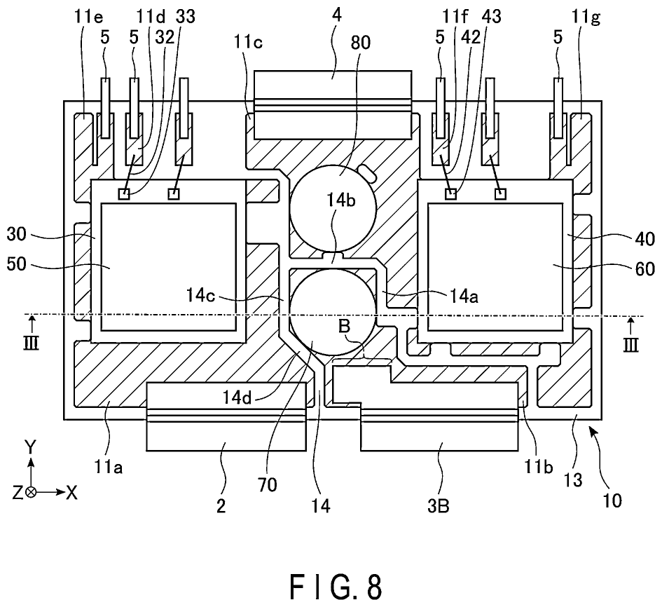

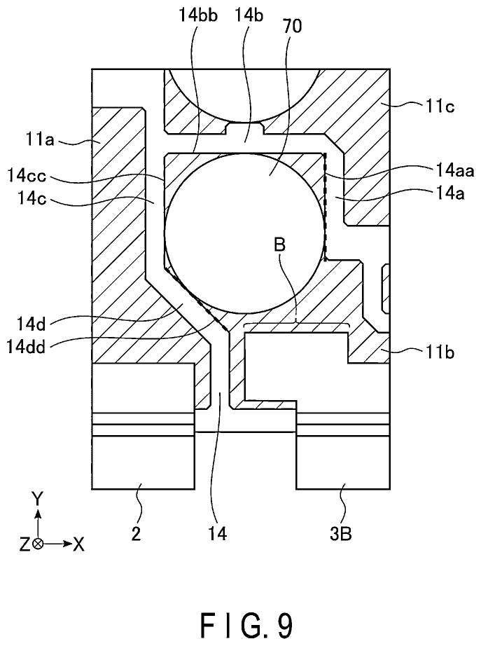

The configuration of the semiconductor device according to the third embodiment will be described with reference to FIGS. 8 and 9. In the semiconductor device of the third embodiment, the shape of a plate terminal 3B differs from that of the plate terminal of each of the first and second embodiments. The other configurations are the same as those of the first and second embodiments.

FIG. 8 is a plan view showing the configuration of the semiconductor device according to the third embodiment. FIG. 9 is an enlarged view of the periphery of an inter-substrate spacer 70 in the semiconductor device of the third embodiment.

The plate terminal 3B is located at one end of the conductive pattern 11b in the Y direction. The plate terminal 3B has a protruding portion B at one end in the X direction and at the other end in the Y direction. That is, the plate terminal 3B has a rectangular shape and includes a protruding portion B which is a rectangular portion protruding from one end of the rectangular shape in the X direction and which is a rectangular portion protruding from the other end of the rectangular shape in the Y direction. In other words, the plate terminal 3B includes a rectangular portion having a rectangular shape and a protruding portion B that protrudes from one end of the rectangular portion in the X direction and from the other end of the rectangular portion in the Y direction. The distance from one end of the rectangular portion in the X direction or the protruding portion B to the inter-substrate spacer 70 is shorter than the distance from the other end of the rectangular portion in the X direction to the inter-substrate spacer 70.

The protruding portion B overlaps the conductive pattern 11b in the Z direction. The plate terminal 3B including the protruding portion B is bonded to the conductive pattern 11b with a solder material therebetween and is electrically connected to the conductive pattern 11b. The thickness of the plate terminal 3B is, for example, 0.8 mm.

In the third embodiment, the plate terminal 3B the area of which is larger than that of each of the plate terminals 3 and 3A is electrically connected to the conductive pattern 11b. That is, in the third embodiment, in addition to the plate terminal 3 of the first embodiment, the protruding portion B is also electrically connected to the conductive pattern 11b.

The conductive pattern 11b close to one end of the plate terminal 3B in the X direction and the other end thereof in the Y direction is a current path through which current intensively flows between the plate terminal 3B and the inter-substrate spacer 70. Since the protruding portion B is provided on the current path, only the conductive pattern 11b can be used to shorten the current flow path.

Thus, the resistance and inductance can be further lowered at the plate terminal 3B and conductive pattern 11b.

As described above, according to the semiconductor device of the third embodiment, providing the plate terminal 3B having an increased area in addition to the structure of the first embodiment makes it possible to lower the resistance and inductance of the conductive patterns (or circuit patterns) on the insulated circuit board more than in the first and second embodiments.

The first to third embodiments described above are directed to an example in which a semiconductor device is a MOS field effect transistor (MOSFET). However, the semiconductor device may be another switching element such as an insulated gate bipolar transistor (IGBT). If the semiconductor device is an IGBT, the source corresponds to an emitter and the drain corresponds to a collector.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

What is claimed is:

1. A semiconductor device comprising:
a first insulated circuit board including a first conductive plate, a second conductive plate, and a first insulating substrate provided between the first conductive plate and the second conductive plate;
a second insulated circuit board including a third conductive plate, a fourth conductive plate, and a second insulating substrate provided between the third conductive plate and the fourth conductive plate;
a first semiconductor chip provided between the first insulated circuit board and the second insulated circuit board; and
a first spacer provided between the first insulated circuit board and the second insulated circuit board,
wherein:
the first conductive plate has a first conductive pattern;
the first spacer is placed on the first conductive pattern;
the first conductive pattern has a first side, a second side, a third side and a fourth side which surround the first spacer;
the first side extends in a first direction;
the second side continues to the first side and extends in a second direction that is orthogonal to the first direction;
the third side continues to the second side and extends in the first direction; and
the fourth side continues to the third side and extends obliquely to the first direction and the second direction.

2. The semiconductor device according to claim 1, wherein an interval between the first side and the fourth side decreases toward a direction away from the first spacer.

3. The semiconductor device according to claim 2, wherein the interval between the first side and the fourth side is smaller than a diameter of the first spacer.

4. The semiconductor device according to claim 1, wherein the first side, the second side, the third side and the fourth side each extend linearly.

5. The semiconductor device according to claim 1, wherein:
the first conductive plate includes the first conductive pattern, a second conductive pattern and a third conductive pattern; and
a slit from which the first conductive plate is removed is provided around the first spacer between the first conductive pattern and the second conductive pattern and between the first conductive pattern and the third conductive pattern.

6. The semiconductor device according to claim 5, wherein:
the slit includes a first portion, a second portion, a third portion and a fourth portion;
the first portion extends in the first direction;
the second portion continues to the first portion and extends in the second direction that is orthogonal to the first direction;
the third portion continues to the second portion and extends in the first direction; and
the fourth portion continues to the third portion and extends obliquely to the first direction and the second direction.

7. The semiconductor device according to claim 1, further comprising:
a second semiconductor chip provided between the first insulated circuit board and the second insulated circuit board;
a second spacer provided between the first insulated circuit board and the second insulated circuit board;
a third spacer provided between the first semiconductor chip and the second insulated circuit board; and
a fourth spacer provided between the second semiconductor chip and the second insulated circuit board.

8. The semiconductor device according to claim 1, further comprising a terminal provided at one end of the first conductive pattern in the first direction,
wherein the terminal includes a rectangular portion having a rectangular shape and a protruding portion that protrudes from one end of the rectangular portion in the second direction.

9. The semiconductor device according to claim 8, further comprising a terminal provided at one end of the first conductive pattern in the first direction,
wherein the terminal includes a rectangular portion having a rectangular shape and a protruding portion that protrudes from one end of the rectangular portion in the second direction and from another end of the rectangular portion in the first direction.

10. The semiconductor device according to claim 8, wherein a distance from the protruding portion to the first spacer is shorter than a distance from another end of the rectangular portion in the second direction to the first spacer.

11. The semiconductor device according to claim 1, wherein the first semiconductor chip includes a MOS field effect transistor.

12. The semiconductor device according to claim 1, wherein the first semiconductor chip includes an insulated gate bipolar transistor (IGBT).

13. The semiconductor device according to claim 1, wherein the first insulating substrate and the second insulating substrate are ceramic substrates.

14. A semiconductor device comprising:
a first insulated circuit board including a first conductive plate having a first conductive pattern, a second conductive plate, and a first insulating substrate provided between the first conductive plate and the second conductive plate;
a second insulated circuit board including a third conductive plate, a fourth conductive plate, and a second insulating substrate provided between the third conductive plate and the fourth conductive plate;
a first semiconductor chip provided between the first insulated circuit board and the second insulated circuit board;
a first spacer provided between the first insulated circuit board and the second insulated circuit board and located on the first conductive pattern; and
a terminal provided at one end of the first conductive pattern in a first direction,
wherein the terminal includes a rectangular portion having a rectangular shape and a protruding portion that protrudes from one end of the rectangular portion in a second direction that is orthogonal to the first direction.

15. The semiconductor device according to claim 14, wherein a distance from the protruding portion to the first spacer is shorter than a distance from another end of the rectangular portion in the second direction to the first spacer.

16. The semiconductor device according to claim 14, wherein the protruding portion protrudes from another end of the rectangular portion in the first direction.

17. The semiconductor device according to claim 14, wherein:
the first conductive pattern has a first side, a second side, a third side and a fourth side located to surround the first spacer;
the first side extends in the first direction;
the second side continues to the first side and extends in a second direction that is orthogonal to the first direction;
the third side continues to the second side and extends in the first direction; and
the fourth side continues to the third side and extends obliquely to the first direction and the second direction.

18. The semiconductor device according to claim 17, wherein an interval between the first side and the fourth side decreases toward a direction away from the first spacer.

19. The semiconductor device according to claim 18, wherein the interval between the first side and the fourth side is smaller than a diameter of the first spacer.

20. The semiconductor device according to claim 17, wherein the first side, the second side, the third side and the fourth side each extend linearly.
